(19) United States
(12) Patent Application Publication
(10) Pub. No.: US 2016/0276468 A1
(43) Pub. Date: Sep. 22, 2016

(54) SEMICONDUCTOR DEVICE

(71) Applicant: Kabushiki Kaisha Toshiba, Tokyo (JP)

(72) Inventors: Masaru Izumisawa, Kanazawa Ishikawa (JP); Hiroshi Ishibashi, Kanazawa Ishikawa (JP); Hiroshi Ohta, Kanazawa Ishikawa (JP); Hidekazu Saeki, Buzen Fukuoka (JP); Takashi Okuhata, Komatsu Ishikawa (JP); Syotaro Ono, Kanazawa Ishikawa (JP)

(21) Appl. No.: 14/837,939

(22) Filed: Aug. 27, 2015

(30) Foreign Application Priority Data
Mar. 16, 2015 (JP) 2015-052245

(51) Int. Cl. H01L 29/739; H01L 29/423; H01L 29/10

(52) U.S. Cl. CPC H01L 29/7395; H01L 29/1095; H01L 29/42356

(57) ABSTRACT

According to one embodiment, a semiconductor device includes a first semiconductor region of a first conductivity type, a second semiconductor region of a second conductivity type, a third semiconductor region of the first conductivity type, a first electrode, a first insulating layer, and a second electrode. The first semiconductor region includes a first region and a second region. The second semiconductor region is provided on the first semiconductor region in the first region. The third semiconductor region is provided on the first semiconductor region in the second region. The first electrode is provided on the third semiconductor region. The first electrode is electrically connected to the third semiconductor region. The first insulating layer is provided on the first electrode. The second electrode is provided on the second semiconductor region. A portion of the second electrode is positioned on the first insulating layer.

### CROSS-REFERENCE TO RELATED APPLICATIONS

This application is based upon and claims the benefit of priority from Japanese Patent Application No. 2015-052245, filed on Mar. 16, 2015; the entire contents of which are incorporated herein by reference.

### FIELD

Embodiments described herein relate generally to a semiconductor device.

### BACKGROUND

A terminal region is provided around an element region to increase the breakdown voltage in a semiconductor device such as a diode, a MOSFET (Metal Oxide Semiconductor Field Effect Transistor), an IGBT (Insulated Gate Bipolar Transistor), or the like used in applications such as power control, etc. On the cathode side of the terminal region, a semiconductor region and an electrode connected to the semiconductor region may be provided so that the potential of the semiconductor region is substantially equal to the potential of the anode electrode to suppress a depletion layer spreading to the outer edge of the semiconductor device from the element region. In such a case, the electric field strength between the cathode electrode and the electrode connected to the semiconductor region becomes high because the distance between these electrodes is short.

On the other hand, ions included in external materials of the semiconductor device such as a sealing resin, etc., move into the insulating unit provided between these electrodes due to the heat and voltage applied to the semiconductor device when using the semiconductor device or during a reliability test. At this time, if the electric field strength between the electrodes is high, the ions that move into the insulating unit are polarized in the interior of the insulating unit. There are cases where the electric field distribution in the semiconductor region is affected and the breakdown voltage of the semiconductor device degrades due to the polarization of the ions in the interior of the insulating unit.

Therefore, technology is desirable to suppress the fluctuation of the breakdown voltage in a semiconductor device that includes a terminal region, a semiconductor region, and an electrode connected to the semiconductor region.

### BRIEF DESCRIPTION OF THE DRAWINGS

FIG. 1 is a plan view showing the semiconductor device according to the first embodiment;

FIG. 2 is an A-A′ cross-sectional view of FIG. 1;

FIG. 3 is a B-B′ cross-sectional view of FIG. 1;

FIG. 4 is a C-C′ cross-sectional view of FIG. 1;

FIG. 5 is a D-D′ cross-sectional view of FIG. 1;

FIG. 6 is a plan view showing the semiconductor device according to the second embodiment;

FIG. 7 is an A-A′ cross-sectional view of FIG. 6;

FIG. 8 is a plan view showing the semiconductor device according to the third embodiment;

FIG. 9 is an A-A′ cross-sectional view of FIG. 8;

FIG. 10 is a cross-sectional view showing a portion of the semiconductor device according to the fourth embodiment;

FIG. 11 is a plan view showing the semiconductor device 500 according to the fifth embodiment; and

FIG. 12 is an A-A′ cross-sectional view of FIG. 11.

### DETAILED DESCRIPTION

According to one embodiment, a semiconductor device includes a first semiconductor region of a first conductivity type, a second semiconductor region of a second conductivity type, a third semiconductor region of the first conductivity type, a first electrode, a first insulating layer, and a second electrode. The first semiconductor region includes a first region and a second region. The second region is provided around the first region. The second semiconductor region is provided on the first semiconductor region in the first region. The third semiconductor region is provided on the first semiconductor region in the second region. The first electrode is provided on the third semiconductor region. The first electrode is electrically connected to the third semiconductor region. The first insulating layer is provided on the first electrode. The second electrode is provided on the second semiconductor region. The second electrode is electrically connected to the second semiconductor region. A portion of the second electrode is positioned on the first insulating layer.

The embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

An XYZ orthogonal coordinate system is used in the description of the embodiments. Two mutually-orthogonal directions parallel to a major surface of a semiconductor layer S are taken as an X-direction (a third direction) and a Y-direction (a second direction); and a direction orthogonal to both the X-direction and the Y-direction is taken as a Z-direction (a first direction).

In the following description, the notations of n⁺, n, n⁻, p⁺, p, and p⁻ indicate relative levels of the impurity concentrations of the conductivity types. In other words, n⁺ indicates that the n-type impurity concentration is relatively higher than that of n; and n⁻ indicates that the n-type impurity concentration is relatively lower than that of n. p⁺ indicates that the p-type impurity concentration is relatively higher than that of p; and p⁻ indicates that the p-type impurity concentration is relatively lower than that of p.

The embodiments described below may be implemented by reversing the p-type and the n-type of the semiconductor regions.

### First Embodiment

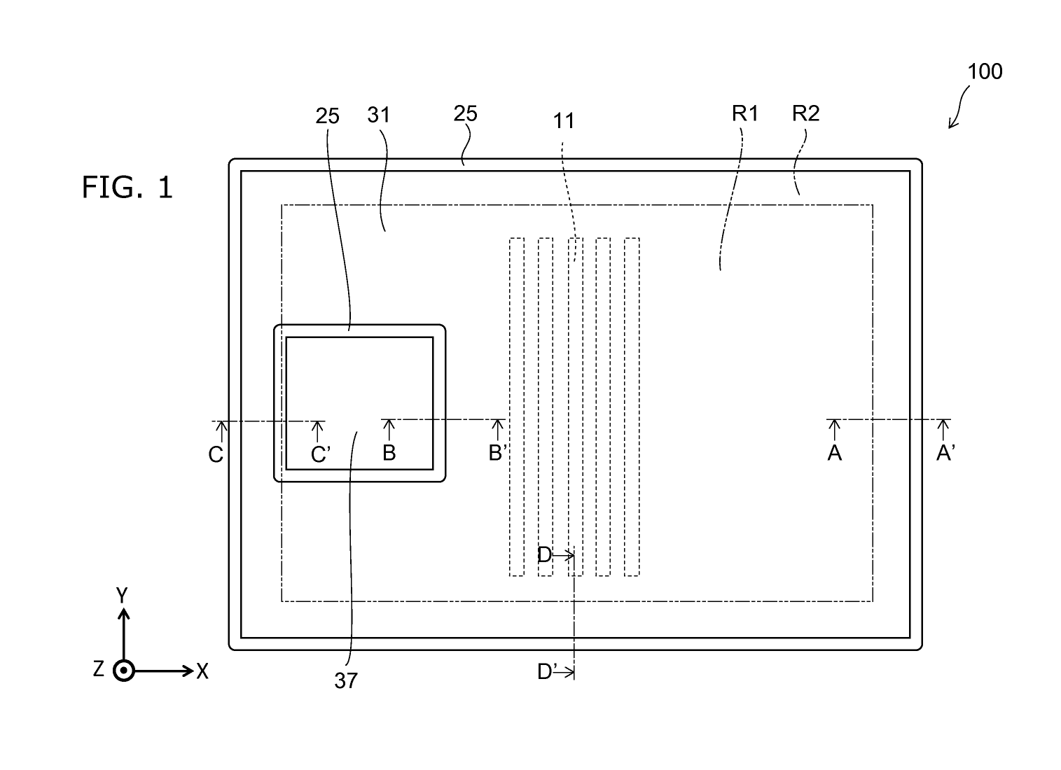

A semiconductor device 100 according to a first embodiment will now be described using FIG. 1 to FIG. 5.

FIG. 1 is a plan view showing the semiconductor device 100 according to the first embodiment.

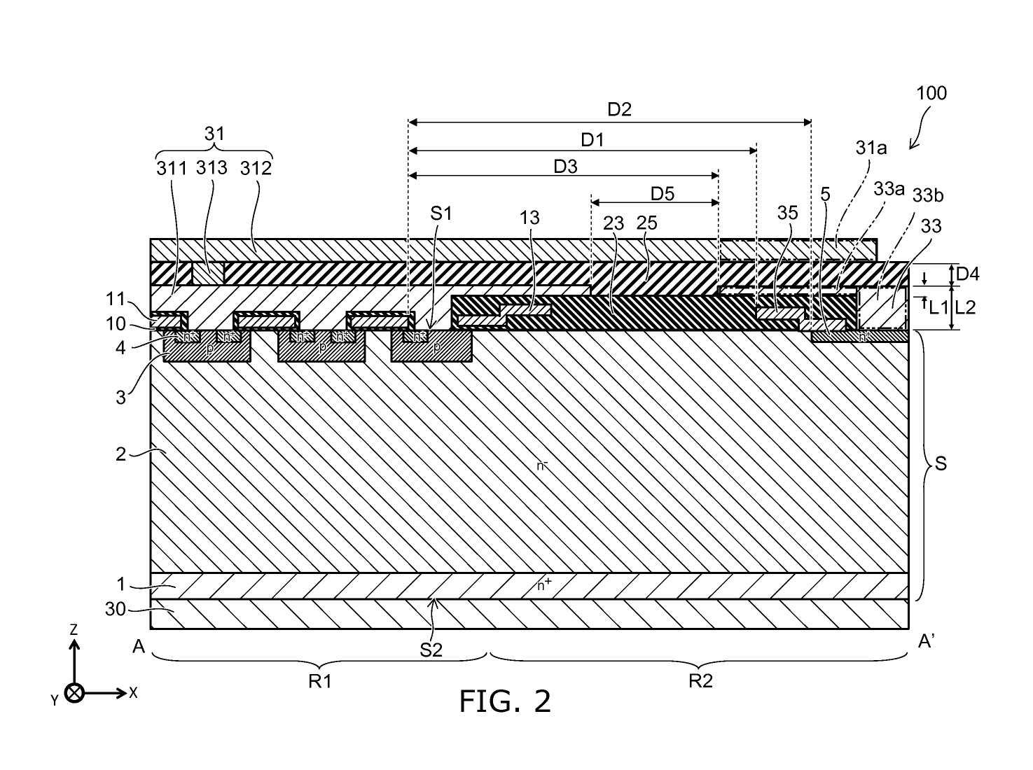

FIG. 2 is an A-A′ cross-sectional view of FIG. 1.

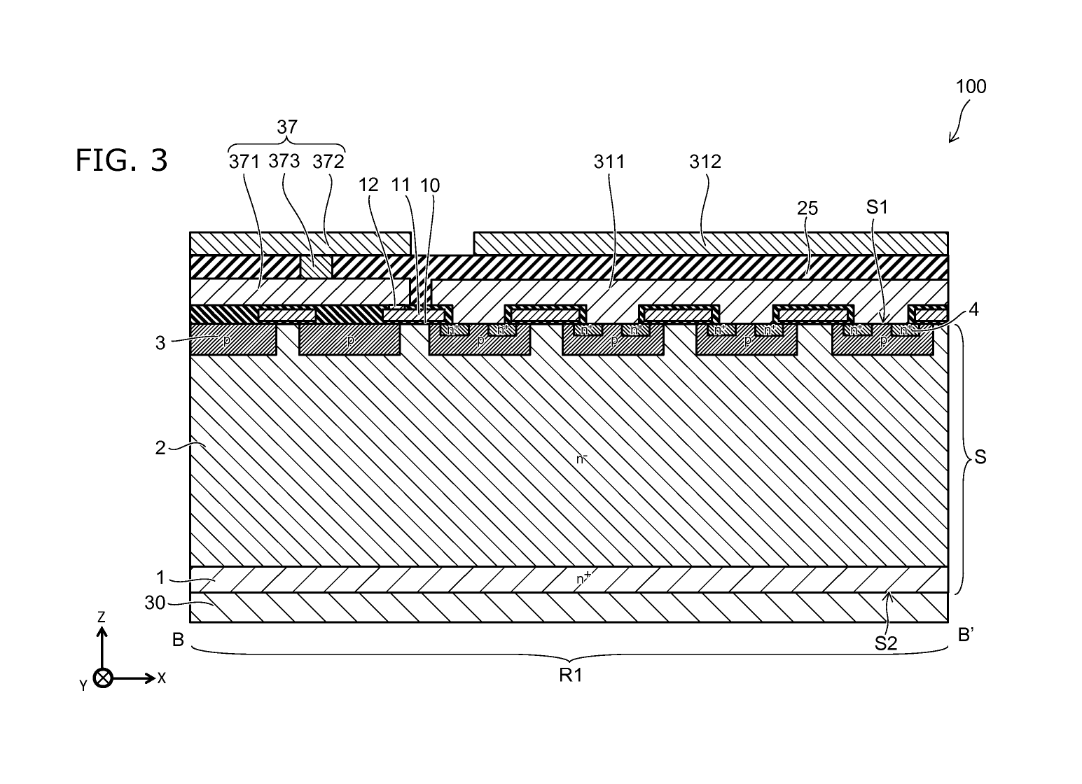

FIG. 3 is a B-B′ cross-sectional view of FIG. 1.

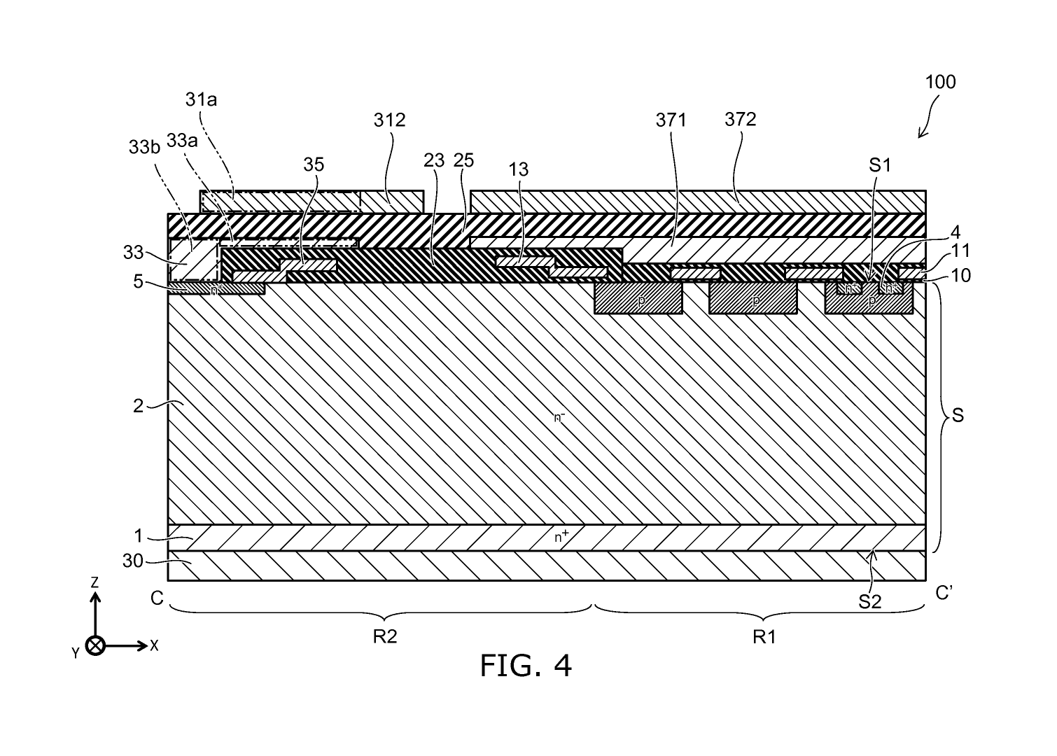

FIG. 4 is a C-C′ cross-sectional view of FIG. 1.

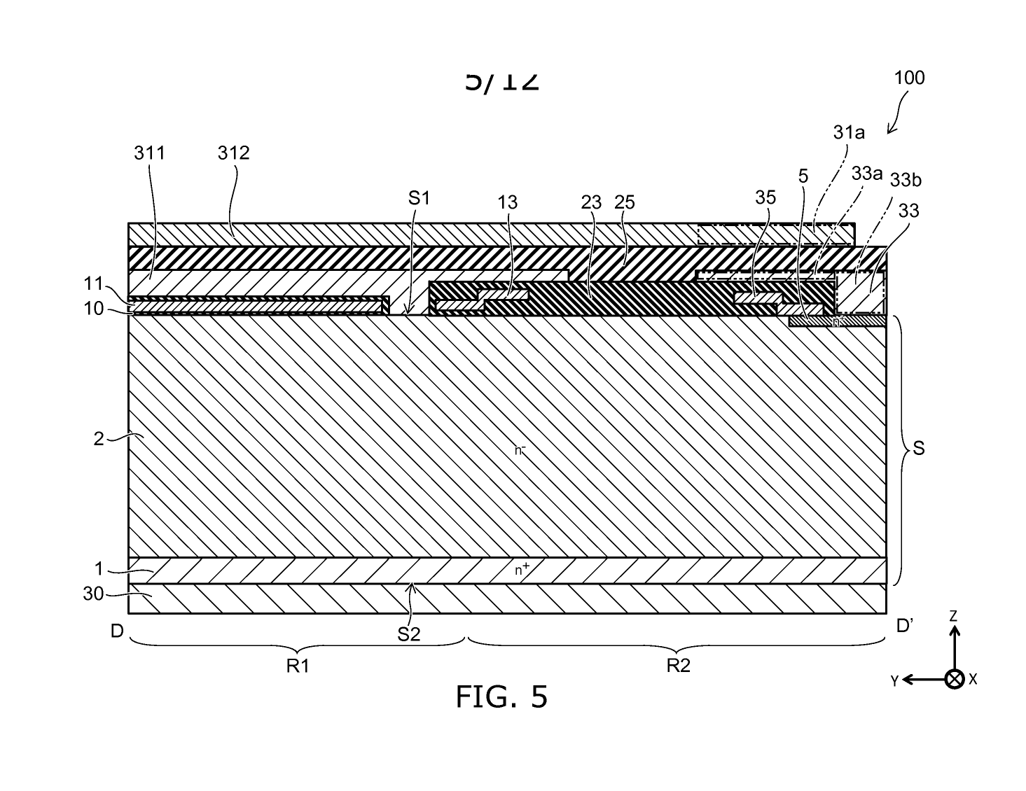

FIG. 5 is a D-D′ cross-sectional view of FIG. 1.

In FIG. 1, some of multiple gate electrodes 11 are illustrated by broken lines.

The semiconductor device 100 according to the first embodiment is, for example, a MOSFET.

The semiconductor device 100 according to the first embodiment includes an n⁺-type drain region 1, an n⁻-type semiconductor region 2 (a first semiconductor region of a first conductivity type), a p-type base region 3 (a second semiconductor region of a second conductivity type), an n⁺-type source region 4 (a fifth semiconductor region of the first conductivity type), an n⁺-type semiconductor region 5 (a third semiconductor region of the first conductivity type), a gate insulation layer 10, a gate electrode 11, a field plate electrode 13, an insulating layer 23, an insulating layer 25 (a first insulating layer), a drain electrode 30, a source electrode 31 (a second electrode), an electrode 33 (a first electrode), an electrode 35, and an electrode 37.

The semiconductor layer S has a front surface S1 and a back surface S2. The source electrode 31 is provided on the front surface S1 side of the semiconductor layer S; and the drain electrode 30 is provided on the back surface S2 side of the semiconductor layer S.

The region inside the double dot-dash line shown in FIG. 1 is an element region R1 (a first region) in which the MOSFET including the p-type base region 3, the n⁺-type source region 4, the gate electrode 11, etc., is formed. On the other hand, the region outside the double dot-dash line shown in FIG. 1 is a terminal region R2 (a second region) not including the MOSFET. As shown in FIG. 1, the terminal region R2 is provided around the element region R1.

As shown in FIG. 2, the n⁺-type drain region 1 is provided on the back surface S2 side of the semiconductor layer S. The n⁺-type drain region 1 is provided in both the element region R1 and the terminal region R2. The n⁺-type drain region 1 is electrically connected to the drain electrode 30.

The n₋-type semiconductor region 2 is provided on the n⁺-type drain region 1 in the element region R1 and the terminal region R2.

The p-type base region 3 is selectively provided on the n₋-type semiconductor region 2 in the element region R1. For example, the p-type base region 3 is multiply provided in the X-direction; and each of the p-type base regions 3 extends in the Y-direction.

The n⁺-type source region 4 is selectively provided on the p-type base region 3 in the front surface S1 portion of the semiconductor layer S. The n⁺-type source region 4 is multiply provided in the X-direction; and each of the n⁺-type source regions 4 extends in the Y-direction.

The gate electrode 11 is provided on the front surface S1 in the element region R1. The gate electrode 11 is multiply provided in the X-direction. Each of the gate electrodes 11 opposes, with the gate insulation layer 10 interposed, a portion of the n₋-type semiconductor region 2, the p-type base region 3, and a portion of the n⁺-type source region 4.

The source electrode 31 is provided on the front surface S1. The p-type base region 3 and the n⁺-type source region 4 are electrically connected to the source electrode 31. An insulating layer is provided between the gate electrode 11 and the source electrode 31; and the gate electrode 11 is electrically isolated from the source electrode 31.

The MOSFET is switched to the on-state by applying a voltage not less than a threshold to the gate electrode 11 in a state in which a voltage that is positive with respect to the source electrode 31 is applied to the drain electrode 30. At this time, a channel (an inversion layer) is formed in the region of the p-type base region 3 at the gate insulation layer 10 vicinity.

The field plate electrode 13 is provided on the front surface S1 in the terminal region R2. The insulating layer 23 is provided around the field plate electrode 13; and the field plate electrode 13 is electrically isolated from the gate electrode 11, the drain electrode 30, and the source electrode 31.

For example, a voltage that is negative with respect to the n₋-type semiconductor region 2 is applied to the field plate electrode 13. The n₋-type semiconductor region 2 around the multiple p-type base regions 3 is depleted by applying a voltage to the field plate electrode 13.

The n⁺-type semiconductor region 5 is provided around the element region R1 on the n₋-type semiconductor region 2 in the terminal region R2.

The electrode 33 is provided on the n⁺-type semiconductor region 5 around the element region R1 and is electrically connected to the n⁺-type semiconductor region 5.

The electrode 33 includes, for example, a first portion 33a and a second portion 33b as shown in FIG. 2. The first portion 33a is provided on the insulating layer 23; and the second portion 33b is provided on the n⁺-type semiconductor region 5. Therefore, a length L1 in the Z-direction of the first portion 33a is shorter than a length L2 in the Z-direction of the second portion 33b.

The electrode 35 is provided around the element region R1. Specifically, the electrode 35 is provided around a portion of the source electrode 31 and the gate electrode 11; and the electrode 33 is provided around the electrode 35. In the Z-direction, a portion of the electrode 35 is provided between the n⁺-type semiconductor region 5 and the first portion 33a; and one other portion of the electrode 35 is provided between the n₋-type semiconductor region 2 and the first portion 33a.

A distance D1 is the distance in the X-direction between the gate electrode 11 and the end portion on the element region R1 side of the electrode 35; a distance D2 is the distance in the X-direction between the n⁺-type semiconductor region 5 and the gate electrode 11; and a distance D3 is the distance in the X-direction between the gate electrode 11 and the end portion on the element region R1 side of the electrode 33.

A portion of the first portion 33a is provided on the element region R1 side of the electrode 35, the second portion 33b, and the n⁺-type semiconductor region 5. A portion of the electrode 35 is provided on the element region R1 side of the n⁺-type semiconductor region 5.

Therefore, as shown in FIG. 2, the distance D1 is longer than the distance D3 but shorter than the distance D2.

The n⁺-type semiconductor region 5 has substantially the same potential as the potential of the n⁺-type drain region 1. Therefore, the electrode 33 and the electrode 35 that are connected to the n⁺-type semiconductor region 5 have substantially the same potential as the potential of the n⁺-type drain region 1. The electrode 35 may be electrically floating. In such a case as well, because the electrode 35 is provided to be proximal to the n⁺-type semiconductor region 5, the potential of the electrode 35 is substantially the same as the potential of the n⁺-type drain region 1.

The source electrode 31 includes, for example, a first source electrode layer 311, a second source electrode layer 312, and a connection unit 313. The second source electrode layer 312 is electrically connected to the first source electrode layer 311 via the connection unit 313.

The first source electrode layer 311 is provided on the front surface S1. The insulating layer 23 is provided between the second portion 33b and a portion of the first source electrode layer 311 in the X-direction and the Y-direction. The insulating layer 25 is provided on the first source electrode layer 311, the insulating layer 23, and the electrode 33; and the second source electrode layer 312 is provided on the insulating layer 25.

The connection unit 313 may be a conductive layer provided to spread along the X-Y plane between the first source electrode layer 311 and the second source electrode layer 312. The position where the connection unit 313 is provided is modifiable as appropriate between the first source electrode layer 311 and the second source electrode layer 312.

The second source electrode layer 312 includes a first portion 31a provided in the terminal region R2. The first portion 31a is positioned on the electrode 33. Specifically, in the Z-direction, the first portion 33a and a portion of the first portion 31a overlap with the insulating layer 25 interposed; and a portion of the first portion 31a and at least a portion of the second portion 33b overlap with the insulating layer 25 interposed. The first portion 31a is provided in an annular configuration along the X-Y plane.

As shown in FIG. 2, for example, a distance D4 which is the shortest distance between the second source electrode layer 312 and the electrode 33 is shorter than a distance D5 which is the shortest distance between the first source electrode layer 311 and the electrode 33.

As shown in FIG. 3, the gate electrode 11 is connected to the electrode 37 via a connection unit 12. The electrode 37 includes, for example, a first electrode layer 371, a second electrode layer 372, and a connection unit 373. The second electrode layer 372 is electrically connected to the first electrode layer 371 via the connection unit 373. The electrode 37 functions as a gate pad and supplies a common gate potential to the multiple gate electrodes 11.

The connection unit 373 may be a conductive layer provided to spread along the X-Y plane between the first electrode layer 371 and the second electrode layer 372. The position where the connection unit 373 is provided is modifiable as appropriate between the first electrode layer 371 and the second electrode layer 372.

An insulating layer is provided between the electrode 37 and the p-type semiconductor region 3; and the electrode 37 is electrically isolated from the semiconductor regions provided inside the semiconductor layer S.

The insulating layer 25 is provided between the first electrode layer 371 and the first source electrode layer 311 in the X-direction and the Y-direction. The second electrode layer 372 is arranged with the first source electrode layer 311 with a gap interposed in the X-direction and the Y-direction. Or, a not-shown insulating layer may be provided between the second electrode layer 372 and the first source electrode layer 311.

The major component of the semiconductor layer S is, for example, silicon. The major component of the semiconductor layer S may be silicon carbide, gallium nitride, gallium arsenide, etc.

The gate electrode 11, the field plate electrode 13, and the electrode 35 include, for example, polycrystalline silicon.

The drain electrode 30, the source electrode 31, and the electrode 33 include, for example, a metal such as aluminum, nickel, copper, titanium, etc.

The gate insulation layer 10, the insulating layer 23, and the insulating layer 25 include, for example, silicon oxide. The insulating layer 23 and the insulating layer 25 may include an oxide of another semiconductor material or an oxide of a metal material.

The operations and effects of the embodiment will now be described.

In the embodiment, the insulating layer 25 is provided on the electrode 33 provided in the terminal region R2; and a portion of the source electrode 31 is provided on the insulating layer 25. By employing such a configuration, it is possible to suppress the fluctuation of the breakdown voltage in the terminal region.

As a comparative example, the case is described where the source electrode 31 does not include the second electrode layer 312 and the connection unit 313. In such a case, an electric field is generated in the X-direction and the Y-direction between the source electrode 31 and the electrode 33. Further, because a portion of the electrode 33 is provided further toward the element region R1 side than are the n⁺-type semiconductor region 5 and the electrode 35, the distance between the electrode 33 and the source electrode 31 is short; and the electric field strength between the electrode 33 and the source electrode 31 is high.

When the electric field strength between the electrode 33 and the source electrode 31 is high, the ions that move to the insulating unit disposed between these electrodes are polarized along the electric field direction. At this time, in the semiconductor device, the direction in which the ions are polarized is the same direction as the direction of the gradient of the potential from the element region R1 toward the terminal region R2. Therefore, the polarization affects the distribution (the spread of the equipotential lines) of the potential inside the semiconductor layer S; and the breakdown voltage of the semiconductor device may fluctuate.

According to the embodiment, it is possible for the direction of the electric field generated between the electrode 33 and the source electrode 31 to be tilted toward the Z-direction with respect to the X-direction and the Y-direction because a portion of the source electrode 31 is provided on the insulating layer 25. In other words, the tilt of the direction of the electric field with respect to the X-direction and the Y-direction can be large. Therefore, even in the case where the polarization of the ions occurs in the insulating unit between the electrode 33 and the source electrode 31, the effects of the polarization on the breakdown voltage of the semiconductor device can be reduced.

In such a case, it is possible for the direction of the electric field generated between the electrode 33 and the source electrode 31 to be oriented more in the Z-direction because the portion of the source electrode 31 and at least a portion of the electrode 33 overlap with the insulating layer 25 interposed in the Z-direction. In other words, the tilt of the direction of the electric field with respect to the X-direction and the Y-direction can be larger. As a result, the effects on the breakdown voltage of the semiconductor device of the polarization of the ions occurring in the insulating unit between the electrode 33 and the source electrode 31 can be reduced even further.

By setting the shortest distance D7 between the second source electrode layer 312 and the electrode 33 to be shorter than the shortest distance D8 between the first source electrode layer 311 and the electrode 33, it is possible for the direction of the electric field generated between the electrode 33 and the source electrode 31 to be oriented more favorably in the Z-direction.

### Second Embodiment

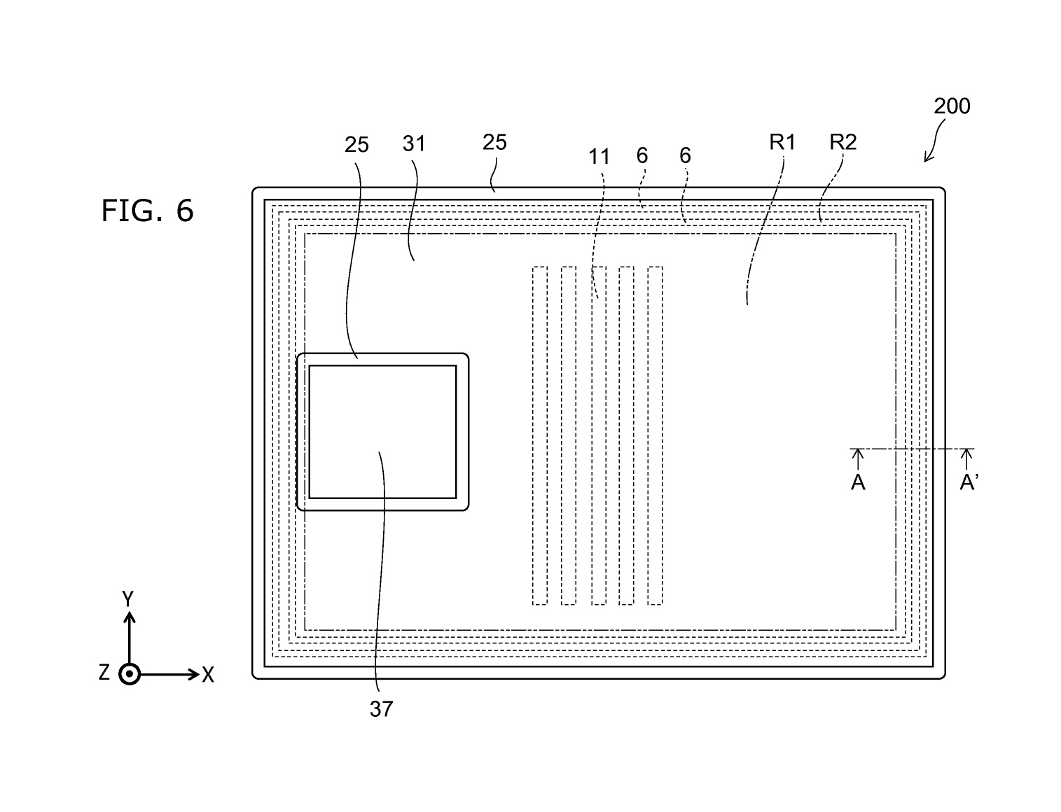

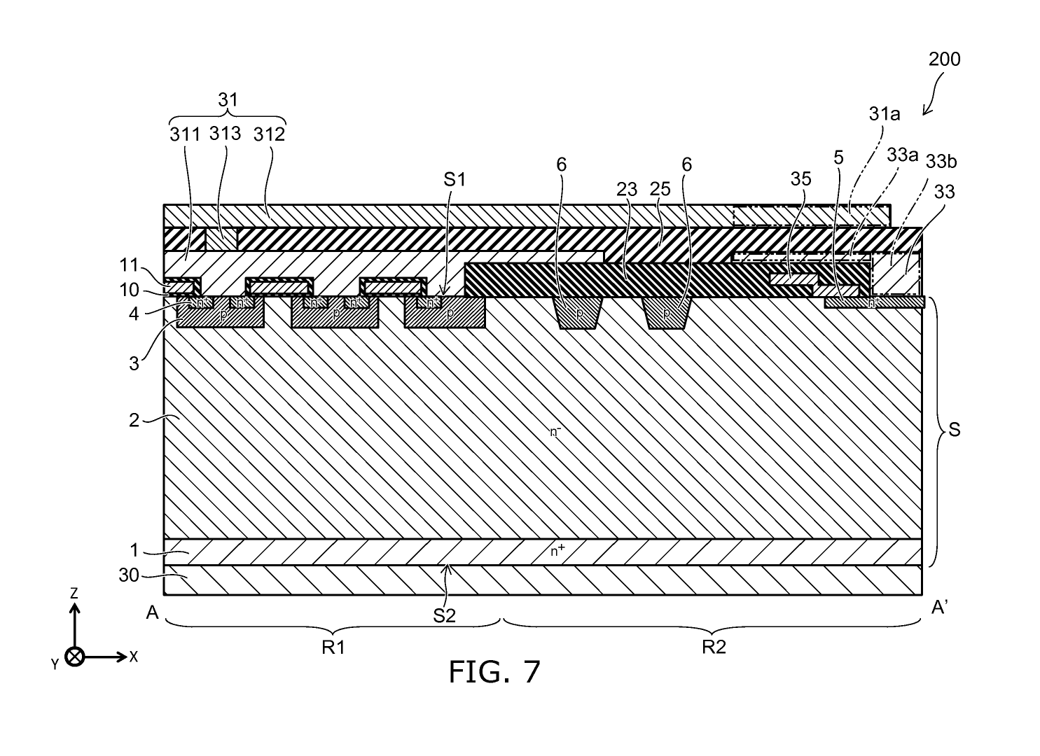

A semiconductor device 200 according to a second embodiment will now be described using FIG. 6 and FIG. 7.

FIG. 6 is a plan view showing the semiconductor device 200 according to the second embodiment.

FIG. 7 is an A-A′ cross-sectional view of FIG. 6.

In FIG. 6, p-type semiconductor regions 6 and some of the gate electrodes 11 are illustrated by broken lines.

For example, the semiconductor device 200 differs from the semiconductor device 100 in that the semiconductor device 200 includes the p-type semiconductor region 6 but does not include the field plate electrode 13.

As shown in FIG. 6, the p-type semiconductor region 6 is provided in an annular configuration in the terminal region R2. For example, the p-type semiconductor region 6 is multiply provided. One p-type semiconductor region 6 is provided around one other p-type semiconductor region 6.

As shown in FIG. 6 and FIG. 7, the p-type semiconductor regions 6 are provided around the multiple p-type base regions 3 and the multiple n⁺-type sources region 4. The n⁺-type semiconductor region 5 is provided around the p-type semiconductor regions 6. The number of p-type semiconductor regions 6 shown in FIG. 6 is an example; and the number of p-type semiconductor regions 6 may be higher or lower.

By providing the p-type semiconductor region 6, a depletion layer spreads from the junction surface between the n₋-type semiconductor region 2 and the p-type semiconductor region 6. Therefore, it is possible to suppress the electric field concentration in the p-type base region 3 positioned at the end in the X-direction or the Y-direction of the multiple p-type base regions 3.

On the other hand, because the p-type semiconductor region 6 is provided, there is a portion where the electric field strength is locally high on the front surface S1 side of the terminal region R2. In the case where the ions moving along the electric field between the electrode 33 and the source electrode 31 are attracted by the electric field generated by the p-type semiconductor region 6, the distribution of the potential in the terminal region R2 becomes unstable; and the breakdown voltage of the semiconductor device fluctuates easily.

According to the embodiment, it is possible to set the direction of the electric field generated between the electrode 33 and the source electrode 31 to be tilted toward the Z-direction with respect to the X-direction and the Y-direction. Accordingly, the embodiment is particularly effective in the case where the semiconductor device includes the p-type semiconductor region 6. By applying the embodiment to a semiconductor device including the p-type semiconductor region 6, it is possible to suppress the fluctuation of the breakdown voltage while increasing the breakdown voltage.

### Third Embodiment

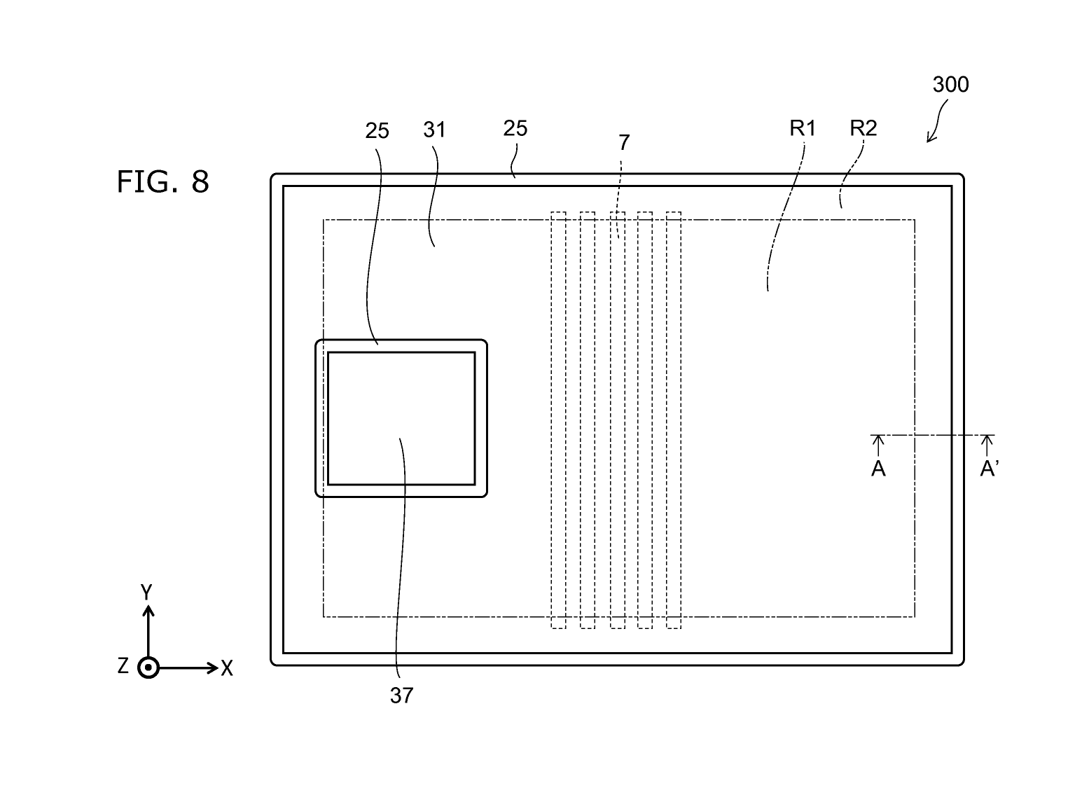

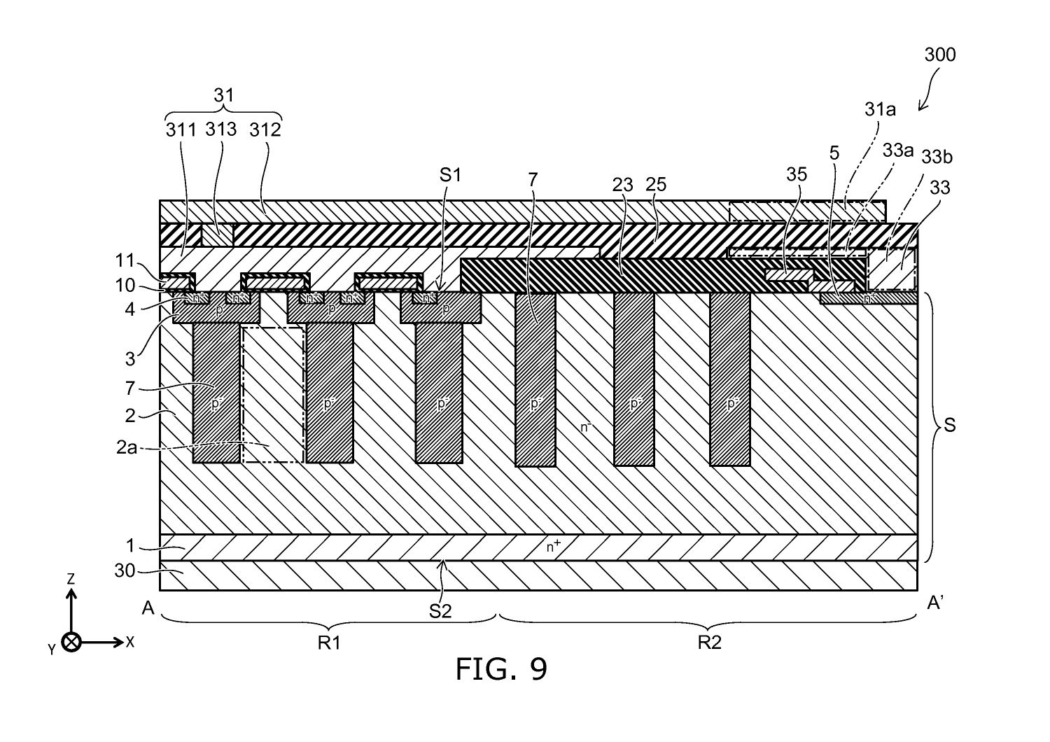

A semiconductor device 300 according to a third embodiment will now be described using FIG. 8 and FIG. 9.

FIG. 8 is a plan view showing the semiconductor device 300 according to the third embodiment.

FIG. 9 is an A-A′ cross-sectional view of FIG. 8.

To describe the structure of the semiconductor device 200 in FIG. 8, some of the positions where p₋-type semiconductor regions 7 are provided are illustrated by broken lines.

For example, the semiconductor device 300 differs from the semiconductor device 100 in that the semiconductor device 300 includes the p₋-type semiconductor regions 7 but does not include the field plate electrode 13.

For example, the p₋-type semiconductor regions 7 are multiply provided in the X-direction as shown in FIG. 8. For example, each of the p₋-type semiconductor regions 7 extends in the Y-direction aligned with the gate electrode 11. A portion of the p₋-type semiconductor regions 7 is provided in the terminal region R2.

The configuration is not limited to the example shown in FIG. 8; and, for example, the p₋-type semiconductor regions 7 may be multiply provided in the Y-direction; and each of the p₋-type semiconductor regions 7 may extend in the X-direction. Or, the p₋-type semiconductor regions 7 may be multiply provided in the X-direction and the Y-direction. Or, the p₋-type semiconductor regions 7 may be multiply provided in annular configurations.

As shown in FIG. 9, the p₋-type semiconductor regions 7 are multiply provided inside the semiconductor layer S. A portion of the multiple p₋-type semiconductor regions 7 is provided in the element region R1; and one other portion of the multiple p-type semiconductor regions is provided in the terminal region R2.

In the element region R1, the p-type base regions 3 are provided on the p₋-type semiconductor regions 7. In the terminal region R2, the insulating layers 23 and 25 are positioned on the p₋-type semiconductor regions 7.

For example, the impurity concentration of the p₋-type semiconductor regions 7 is set so that the total amount of the p-type impurity included in the p₋-type semiconductor regions 7 is equal to the total amount of the n-type impurity included in an n₋-type semiconductor region 2a positioned between the p₋-type semiconductor regions 7. The n₋-type semiconductor region 2a and the p₋-type semiconductor regions 7 are included in a super junction structure.

When the MOSFET is in the off-state and a positive potential with respect to the potential of the source electrode 31 is applied to the drain electrode 30, a depletion layer spreads from the p-n junction surface between the n₋-type semiconductor region 2a and the p₋-type semiconductor regions 7. A high breakdown voltage is obtained because the n₋-type semiconductor region 2a and the p₋-type semiconductor regions 7 are depleted in directions perpendicular to the junction surfaces between the n₋-type semiconductor region 2a and the p₋-type semiconductor regions 7 and because the electric field concentration is suppressed in the direction parallel to the junction surfaces between the n₋-type semiconductor region 2a and the p₋-type semiconductor regions 7.

However, in the case where the p₋-type semiconductor regions 7 are provided, the electric field strength on the front surface S1 side of the terminal region R2 is high compared to the case where the p₋-type semiconductor regions 7 are not provided. Therefore, due to the electric field between the electrode 33 and the source electrode 31, the distribution of the potential in the terminal region R2 becomes unstable; and the breakdown voltage of the semiconductor device fluctuates easily.

According to the embodiment, it is possible to set the direction of the electric field generated between the electrode 33 and the source electrode 31 to be tilted toward the Z-direction with respect to the X-direction and the Y-direction. Accordingly, the embodiment is particularly effective in the case where the semiconductor device includes the p⁻-type semiconductor regions 7. By applying the embodiment to a semiconductor device including the p₋-type semiconductor regions 7, it is possible to suppress the fluctuation of the breakdown voltage while increasing the breakdown voltage.

In the first to third embodiments of the invention, a planar-type MOSFET in which the gate electrode 11 is formed on the semiconductor layer S is described as an example. However, the embodiments are not limited to planar-type MOSFETs; and the embodiments are applicable also to a trench-type MOSFET in which the gate electrode 11 is provided inside the semiconductor layer S.

### Fourth Embodiment

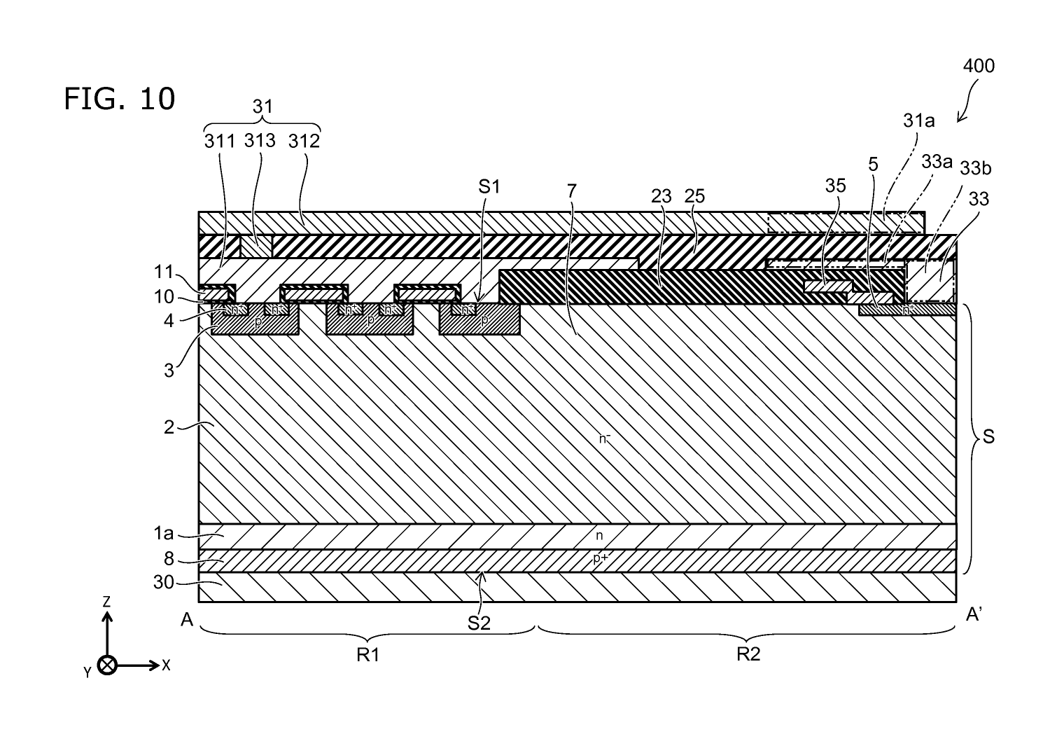

A semiconductor device 400 according to a fourth embodiment will now be described using FIG. 10.

FIG. 10 is a cross-sectional view showing a portion of the semiconductor device 400 according to the fourth embodiment.

The semiconductor device 400 according to the fourth embodiment is, for example, an IGBT.

The semiconductor device 400 according to the fourth embodiment includes a p⁺-type collector region 8, an n-type semiconductor region 1a, the n₋-type semiconductor region 2 (the first semiconductor region of the first conductivity type), the p-type base region 3 (the second semiconductor region of the second conductivity type), the n⁺-type emitter region 4 (the fifth semiconductor region), the n⁺-type semiconductor region 5 (the third semiconductor region), the gate insulation layer 10, the gate electrode 11, the insulating layer 23, the insulating layer 25 (the first insulating layer), a collector electrode 30, an emitter electrode 31 (the second electrode), the electrode 33 (the first electrode), the electrode 35, and the electrode 37 (the third electrode).

The semiconductor device 400 differs from the semiconductor device 100 in that the semiconductor device 400 further includes the p⁺-type collector region 8 and functions as an IGBT. In the semiconductor device 400, the electrode 31 is the emitter electrode; and the electrode 30 is the collector electrode.

For example, instead of the n⁺-type semiconductor region 1 of the semiconductor device 100, the n-type semiconductor region la is provided between the p⁺-type collector region 8 and the n₋-type semiconductor region 2. The n-type semiconductor region la may function as a buffer region.

According to the embodiment, it is possible to suppress the fluctuation of the breakdown voltage due to the electric field generated between the electrode 33 and the emitter electrode 31 in an IGBT.

### Fifth Embodiment

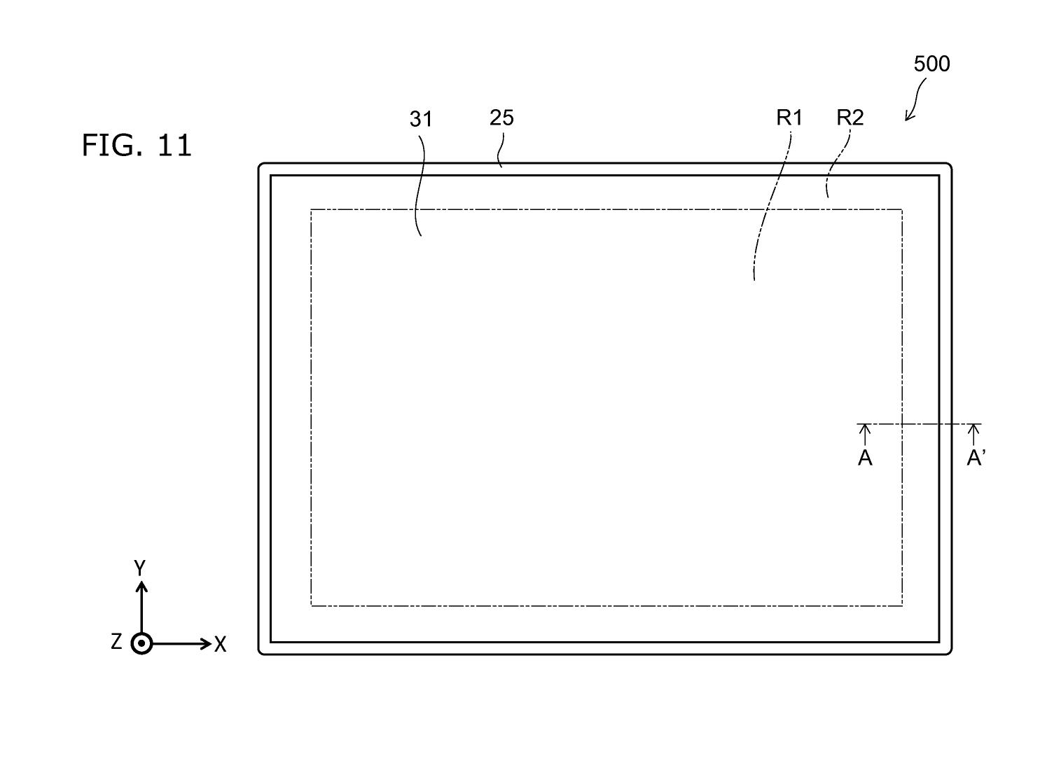

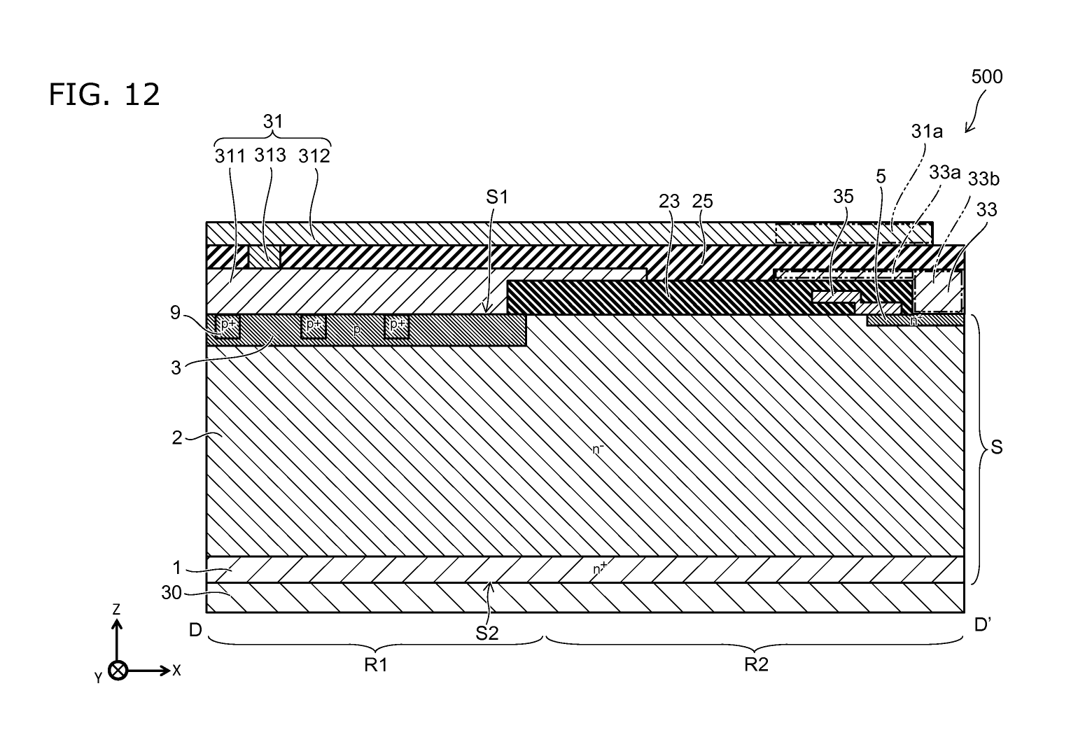

A semiconductor device 500 according to a fifth embodiment will now be described using FIG. 11 and FIG. 12.

FIG. 11 is a plan view showing the semiconductor device 500 according to the fifth embodiment.

FIG. 12 is an A-A′ cross-sectional view of FIG. 11. The semiconductor device 500 according to the fifth embodiment is, for example, a diode.

The semiconductor device 500 according to the fifth embodiment includes the n⁺-type semiconductor region 1, the n₋-type semiconductor region 2 (the first semiconductor region of the first conductivity type), the p-type semiconductor region 3 (the second semiconductor region of the second conductivity type), a p⁺-type semiconductor region 9, the n⁺-type semiconductor region 5 (the third semiconductor region), the insulating layer 23, the insulating layer 25 (the first insulating layer), an anode electrode 30, a cathode electrode 31 (the second electrode), the electrode 33 (the first electrode), and the electrode 35.

In the semiconductor device 500, the electrode 31 is the cathode electrode; and the electrode 30 is the anode electrode. As shown in FIG. 11, the cathode electrode 31 is provided in the element region R1 and the terminal region R2.

As shown in FIG. 12, in the element region R1, the p-type semiconductor region 3 is provided on the n₋-type semiconductor region 2. For example, the p⁺-type semiconductor region 9 is selectively provided on the p-type semiconductor region 3. The p⁺-type semiconductor region 9 may be provided on the entire surface of the p-type semiconductor region 3.

The p⁺-type semiconductor region 9 may pierce the p-type semiconductor region 3; and a portion of the p⁺-type semiconductor region 9 may reach the n₋-type semiconductor region 2. In other words, the p-type semiconductor region 3 may be provided around a portion of the p⁺-type semiconductor region 9; and the n₋-type semiconductor region 2 may be provided around one other portion of the p⁺-type semiconductor region 9.

The p-type semiconductor region 3 and the p⁺-type semiconductor region 9 are electrically connected to the cathode electrode 31. A structure similar to the source electrode 31 described in the first embodiment is employable as the structure of the cathode electrode 31. Otherwise, for example, structures similar to the structures described in the first embodiment are employable as the structures of the electrode 33 and the electrode 35. Similarly to the first embodiment, the n⁺-type semiconductor region 5, the electrode 33, and the electrode 35 have substantially the same potential as the potential of the anode electrode 30.

In the embodiment, similarly to the first embodiment, the fluctuation of the breakdown voltage of the semiconductor device due to the electric field generated between the electrode 33 and the cathode electrode 31 can be suppressed.

The carrier concentrations of the semiconductor regions can be considered to be equal to the effective impurity concentrations of the semiconductor regions. Accordingly, in the embodiments described above, it is possible to confirm the relative levels of the impurity concentrations of the semiconductor regions using, for example, a SCM (scanning capacitance microscope).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first semiconductor region of a first conductivity type including a first region and a second region, the second region being provided around the first region;
a second semiconductor region of a second conductivity type provided on the first semiconductor region in the first region;
a third semiconductor region of the first conductivity type provided on the first semiconductor region in the second region;
a first electrode provided on the third semiconductor region, the first electrode being electrically connected to the third semiconductor region;
a first insulating layer provided on the first electrode; and
a second electrode provided on the second semiconductor region, the second electrode being electrically connected to the second semiconductor region, a portion of the second electrode being positioned on the first insulating layer.

2. The device according to claim 1, wherein a portion of the first electrode is provided on the first region side of the third semiconductor region.

3. The device according to claim 2, wherein
the second electrode includes a first portion,
the first portion and at least a portion of the first electrode overlap in a first direction with the first insulating layer interposed, and
The first direction is from the first semiconductor region toward the second semiconductor region.

4. The device according to claim 3, wherein the first portion is provided in an annular configuration.

5. The device according to claim 1, further comprising a fourth semiconductor region of the second conductivity type provided on the first semiconductor region, the fourth semiconductor region being positioned around the second semiconductor region, the third semiconductor region being provided around the fourth semiconductor region.

6. The device according to claim 1, further comprising:
a fifth semiconductor region of the first conductivity type provided on the second semiconductor region;
a gate electrode; and
a gate insulation layer, at least a portion of the gate insulation layer being provided between the second semiconductor region and the gate electrode.

7. The device according to claim 1, further comprising:
a sixth semiconductor region of the second conductivity type, the second semiconductor region being provided around at least a portion of the sixth semiconductor region, a carrier concentration of the second conductivity type of the sixth semiconductor region being higher than a carrier concentration of the second conductivity type of the second semiconductor region.

8. The device according to claim 6, further comprising a third electrode provided on the gate electrode, the third electrode being electrically connected to the gate electrode, a portion of the third electrode being provided on the first insulating layer.

9. The device according to claim 6, further comprising a plurality of seventh semiconductor regions of the second conductivity type, each of the seventh semiconductor regions being provided between the first semiconductor region and the second semiconductor region, the first semiconductor region being provided around each of the seventh semiconductor regions.

10. The device according to claim 9, wherein
each of the seventh semiconductor regions extends in a second direction perpendicular to the first direction that is from the first semiconductor region toward the second semiconductor region, and
the plurality of seventh semiconductor regions is arranged in a third direction perpendicular to the first direction and the second direction.

11. The device according to claim 10, wherein a carrier concentration of the second conductivity type of each of the seventh semiconductor regions is lower than a carrier concentration of the second conductivity type of the second semiconductor region.

12. The device according to claim 6, further comprising an eighth semiconductor region of the second conductivity type provided under the first semiconductor region.

13. The device according to claim 12, wherein a carrier concentration of the second conductivity type of the eighth semiconductor region is higher than a carrier concentration of the first conductivity type of the first semiconductor region.

14. The device according to claim 1, wherein the first insulating layer includes an oxide of a semiconductor or an oxide of a metal.

15. The device according to claim 2, further comprising a fourth electrode, the first electrode being provided around the fourth electrode, a portion of the fourth electrode being provided between the first semiconductor region and the portion of the first electrode, one other portion of the fourth electrode being provided between one other portion of the first electrode and a portion of the third semiconductor region.
